(19) United States
(12) Patent Application Publication
(10) Pub. No.: US 2026/0101795 A1
(43) Pub. Date: Apr. 9, 2026

(54) METHOD FOR PRODUCING AN ELECTRONIC COMPONENT

(71) Applicant: ams-OSRAM International GmbH, Regensburg (DE)

(72) Inventors: Christoph Mannal, Schierling (DE); Mathias Wendt, Hausen (DE); Klaus Müller, Pettendorf (DE)

(21) Appl. No.: 19/109,205

(22) PCT Filed: Sep. 12, 2023
(86) PCT No.: PCT/EP2023/075003

§ 371 Date: Mar. 6, 2025

(30) Foreign Application Priority Data
Sep. 13, 2022 (DE) 10 2022 123 324.3

(51) Int. Cl. H10W 72/00; H10H 29/01

(52) U.S. Cl. CPC H10W 72/07232; H10H 29/0364; H10W 72/07236; H10W 72/07241

(57) ABSTRACT

In an embodiment a method includes providing a carrier having an electronic semiconductor chip arranged on the carrier, providing a substrate having a functional layer arranged on the substrate, arranging the substrate over the carrier such that the functional layer faces toward the electronic semiconductor chip, and pressing the substrate onto the carrier, wherein the functional layer is pressed onto the electronic semiconductor chip so that the electronic semiconductor chip is pressed onto the carrier and connected to the carrier, and wherein the functional layer is deformed in response to pressing the electronic semiconductor chip.

### CROSS-REFERENCE TO RELATED APPLICATIONS

This patent application is a national phase filing under section 371 of PCT/EP2023/075003, filed Sep. 12, 2023, which claims the priority of German patent application no. 10 2022 123 324.3, filed Sep. 13, 2022, each of which is incorporated herein by reference in its entirety.

### TECHNICAL FIELD

The present invention relates to a method for producing an electronic component.

### BACKGROUND

The connecting of electronic semiconductor chips to a carrier with the aid of a bonding technique is known from the prior art. After the electronic semiconductor chips have been arranged on the carrier, a sufficient pressure subsequently needs to be applied to the electronic semiconductor chips in order to ensure faultless connecting, or bonding. The electronic semiconductor chips must not be damaged during this, and must not be torn from the carrier.

It is known from the prior art to use nonstick films or nonstick coatings on hard wafers in order to thus be able to exert pressure on the electronic semiconductor chips. One disadvantage of this method is that the use of hard wafers may cause damage to the electronic semiconductor chips. Since the use of nonstick films, or the arranging of nonstick films on wafers, cannot currently be automated, there is furthermore not yet any known method compatible with production and manufacture.

### SUMMARY

Embodiments provide an improved method for producing an electronic component. A method for producing an electronic component comprises the following method steps: A carrier having an electronic semiconductor chip arranged on the carrier is provided. Furthermore, a substrate having a functional layer arranged on the substrate is provided. The substrate is arranged over the carrier in such a way that the functional layer faces toward the electronic semiconductor chip. The substrate is pressed onto the carrier. The functional layer is thereby pressed onto the electronic semiconductor chip, so that the electronic semiconductor chip is pressed onto the carrier and connected to the carrier. The functional layer deforms during the pressing onto the electronic semiconductor chip.

The method is based on a bonding technique, in the scope of which the electronic semiconductor chip is intended to be firmly connected to the carrier. Advantageously, a uniform pressure is exerted on the electronic semiconductor chip by the deformation of the functional layer, so that the electronic semiconductor chip can be connected reliably to the carrier and so that it is possible to prevent the electronic semiconductor chip being damaged during the connecting to the carrier.

It is necessary to ensure deformation of the functional layer at least within a pressure value range that is suitable for the connecting of the electronic semiconductor chip, i.e. besides a deformability or softness of the functional layer, it is also necessary to ensure that the electronic semiconductor chip is on the one hand connected reliably to the carrier during the pressing onto the carrier, and on the other hand that the electronic semiconductor chip is not damaged because an excessively high pressure has been exerted. At the same time, the functional layer must not yield during the pressing onto the electronic semiconductor chip to such an extent that the electronic semiconductor chip is pressed into the functional layer so that pressing of the electronic semiconductor chip onto the carrier is prevented.

In one embodiment, the functional layer is configured to be elastically deformable. Advantageously, an elastic functional layer returns to its original shape after the substrate has been pressed onto the electronic semiconductor chip, i.e. after the substrate facing toward the electronic semiconductor chip with the functional layer has been separated from the electronic semiconductor chip, or from the carrier. The functional layer may therefore be used repeatedly without a topography that is more unfavorable for a uniform pressure distribution on the electronic semiconductor chip being formed on a side of the functional layer facing away from the substrate. It is, however, also possible for the functional layer to be configured to be plastically, or inelastically, deformable.

In one embodiment, the functional layer comprises a polymer, an elastomer, a thermoplastic or an epoxy resin. The functional layer may however also comprise a different material, in particular a plastic. Polymers, elastomers, thermoplastics and epoxy resins advantageously have a sufficient deformability, softness or elasticity in order to bring about pressure equilibration during the connecting of the electronic semiconductor chip to the carrier. The deformability or elasticity of the functional layer may in this case be varied according to the composition and structure of the functional layer. A particularly soft or elastic functional layer may, for example, be necessary when a particularly sensitive electronic semiconductor chip is used, for example an optoelectronic semiconductor chip having sensitive radiation emission surfaces.

In one embodiment, the functional layer comprises benzocyclobutene. Advantageously, benzocyclobutene (BCB) may be arranged on the substrate in a particularly simple way. For example, BCB may be arranged on the substrate by spin coating. After it has been arranged on the substrate, the BCB is at least partially crosslinked, or cured, so that a BCB-based polymer is formed.

In one embodiment, the functional layer comprises graphite. Advantageously, graphite has a sufficient deformability, or elasticity, which makes it possible to connect the electronic semiconductor chip to the carrier reliably and without damage. For example, graphite has a lower bulk modulus and a lower hardness than silicon, which typically is used during the connecting of electronic semiconductor chips in the form of wafers and pressed onto electronic semiconductor chips. Graphite can furthermore be produced and/or arranged on the substrate in a simple way. The graphite may be produced and arranged on the substrate for example by vapor deposition, sputtering or pyrolytically.

In one embodiment, the providing of the substrate comprises arranging the functional layer on the substrate with the aid of a bonding method, vapor deposition or sputtering. Advantageously, the arranging of the functional layer on the substrate may take place in a fully automated fashion, so that the method may also be carried out in a fully automated fashion.

In one embodiment, the functional layer is heated during the pressing of the functional layer onto the electronic semiconductor chip. Advantageously, the deformability of the functional layer or the elasticity of the functional layer may be increased by heating, so that a particularly uniform pressure is exerted on the electronic semiconductor chip and the electronic semiconductor chip is treated particularly gently. The deformability, or elasticity, of the functional layer may advantageously be regulated and optimized by adjusting a desired temperature.

In one embodiment, the substrate and the carrier are separated from one another after the pressing, the functional layer being detached from the electronic semiconductor chip. All materials envisioned and mentioned for the functional layer have the advantage that they entail only minor adhesion to the electronic semiconductor chip. After it has been pressed onto the electronic semiconductor chip, the functional layer may therefore be detached again from the electronic semiconductor chip with particularly little resistance.

In one embodiment, a nonstick layer is arranged on the functional layer. The functional layer is arranged between the substrate and the nonstick layer. The substrate is arranged over the carrier in such a way that the nonstick layer faces toward the electronic semiconductor chip. The nonstick layer is pressed onto the electronic semiconductor chip during the pressing of the substrate onto the carrier.

In one embodiment, the providing of the substrate comprises arranging a nonstick layer on the functional layer. The functional layer is arranged between the substrate and the nonstick layer. The substrate is arranged on the carrier in such a way that the nonstick layer faces toward the electronic semiconductor chip. The nonstick layer is pressed onto the electronic semiconductor chip during the pressing of the substrate onto the carrier.

By the nonstick layer, an adhesion of the electronic semiconductor chip to the substrate and a resistance during the separation of the substrate from the carrier are significantly reduced, or detaching of the substrate from the electronic semiconductor chip is simplified, so that it is advantageously possible to prevent the electronic semiconductor chip being detached from the carrier again after it has been pressed onto the latter. Furthermore, because of the presence of the nonstick layer, the functional layer does not creep under the electronic semiconductor chip, so that detaching of the electronic semiconductor chip from the carrier may likewise be prevented.

Further, the nonstick layer makes it possible to connect the electronic semiconductor chip to the carrier with particularly little residue, i.e. no material of the functional layer remains on the electronic semiconductor chip. This is advantageous particularly in respect of optoelectronic semiconductor chips that have, for example, radiation emission surfaces or radiation detection surfaces on their upper sides.

The arranging of the nonstick layer on the functional layer takes place by vapor deposition, sputtering or spin coating. Advantageously, no manual arranging of the nonstick layer on the functional layer is necessary, i.e. for example arranging with the aid of a tool, for example with the aid of a gripping tool, for example with the aid of a tweezer tool. The arranging of the nonstick layer may therefore take place in an automated fashion, so that the entire method may be carried out in an automated fashion.

In one embodiment, the nonstick layer comprises a fluorinated material. Advantageously, fluorinated materials are particularly suitable for imparting nonstick properties. The nonstick properties of fluorinated materials are, for example, known from Teflon.

In one embodiment, the nonstick layer comprises perfluorodecyltrichlorosilane. Advantageously, perfluorodecyltrichlorosilane (FDTS) may be arranged on the functional layer in the form of a particularly thin nonstick layer, and it may in particular be deposited in the form of a self-organized molecular monolayer (self-assembled monolayer, SAM), so that the arranging of the nonstick layer on the functional layer can take place particularly rapidly and efficiently, and by using very little material. By the functional silane group of the FDTS, molecules of the nonstick layer are bonded chemically and for this reason particularly reliably to the functional layer, so that the nonstick layer is connected reliably to the functional layer and detaching of the nonstick layer can be avoided.

Instead of the fully fluorinated FDTS, an only partially fluorinated material may also be used. Other functional groups may also be used for the bonding of the nonstick layer to the functional layer. The nonstick properties may be varied in a versatile fashion by selection of the degree of the fluorination, the other chemical composition and the molecular length.

The arranging of the fluorinated material, or of the FDTS or other material of the nonstick layer, on the functional layer may likewise take place by vapor deposition or spin coating. Furthermore, the nonstick layer may be generated by immersion, for example immersion in an FDTS solution. All preparation techniques advantageously enable rapid production and regeneration of the nonstick layer, for instance after the nonstick layer has been used for a predefined period of time or in order to produce a predefined number of electronic components.

In one embodiment, the nonstick layer comprises a metallic material, in particular titanium or gold. Advantageously, metallic materials such as gold and oxidized titanium form inert surfaces that may be used as nonstick layers, which enable almost resistance-free detaching of the substrate. Metallic materials such as gold and titanium can furthermore be connected efficiently to a graphite functional layer.

In one embodiment, the substrate and the carrier are separated from one another after the pressing, the nonstick layer being detached from the electronic semiconductor chip. The nonstick layer can advantageously be detached from the electronic semiconductor chip with almost no resistance. Detaching of the electronic semiconductor chip from the carrier may therefore advantageously be prevented.

In one embodiment, the electronic semiconductor chip is configured as an optoelectronic semiconductor chip. Advantageously, the method makes it possible that even particularly sensitive semiconductor chips, for example light-emitting diodes, photodiodes and laser diodes having sensitive radiation emission surfaces or radiation detection surfaces can be connected gently to the carrier. By selection of material of the functional layer, a deformability or elasticity of the functional layer may be selected. For sensitive semiconductor chips, a particularly soft or particularly elastic functional layer may therefore advantageously be selected. Furthermore, an application pressure and a process temperature, which in turn influences the elasticity of the functional layer, may be selected in such a way that the semiconductor chip is connected particularly gently to the carrier.

In one embodiment, a solder material is arranged between the electronic semiconductor chip and the carrier. Advantageously, the method makes it possible that the connection mediated by the solder material between the electronic semiconductor chip and the carrier can be formed particularly uniformly and efficiently.

It is not, however, absolutely necessary for a solder material to be arranged between the electronic semiconductor chip and the carrier. Instead, the electronic semiconductor chip may be connected to the carrier by a different bonding technique, for example by direct bonding. In this case, chemical bonds are generated at the interface between the electronic semiconductor chip and the carrier.

In one embodiment, the carrier is heated during the pressing of the functional layer onto the electronic semiconductor chip. The heating of the carrier may advantageously improve the rheological properties of the solder material, so that it can be distributed uniformly between the electronic semiconductor chip and the carrier in order to ensure a reliable connection between the electronic semiconductor chip and the carrier. The heating of the carrier may also be necessary in order to generate a direct bond connection between the electronic semiconductor chip and the carrier.

In one embodiment, the carrier is provided having a plurality of electronic semiconductor chips arranged on the carrier.

If the carrier is equipped with a plurality of electronic or optoelectronic semiconductor chips, the semiconductor chips may have different heights in relation to the carrier. This may, for example, be the case in particular when a solder material is arranged between the carrier and the semiconductor chips. It may, for example, also be that an electronic semiconductor chip is arranged not exactly parallel but slightly obliquely in relation to the carrier, which is likewise exacerbated for example by a solder material between the carrier and the electronic semiconductor chip.

Advantageously, different heights and/or tilts of electronic semiconductor chips may be compensated for particularly gently in the scope of the method since, during the pressing of the substrate onto the carrier, a pressure is initially exerted on more highly arranged electronic semiconductor chips and/or more highly arranged portions of tilted electronic semiconductor chips, but the functional layer deforms during the pressing onto the electronic semiconductor chips and locally intensified compressive stresses on the electronic semiconductor chip or the electronic semiconductor chips are thereby avoided.

### BRIEF DESCRIPTION OF THE DRAWINGS

The above-described properties, features and advantages of this invention, as well as the way in which they are achieved, will become clearer and more easily understandable in conjunction with the following description of the exemplary embodiments, which are explained in more detail in connection with the drawings.

FIG. 1 shows method steps of a method for producing an electronic component; and

FIG. 2: shows a variant of the method of FIG. 1.

### DETAILED DESCRIPTION OF ILLUSTRATIVE EMBODIMENTS

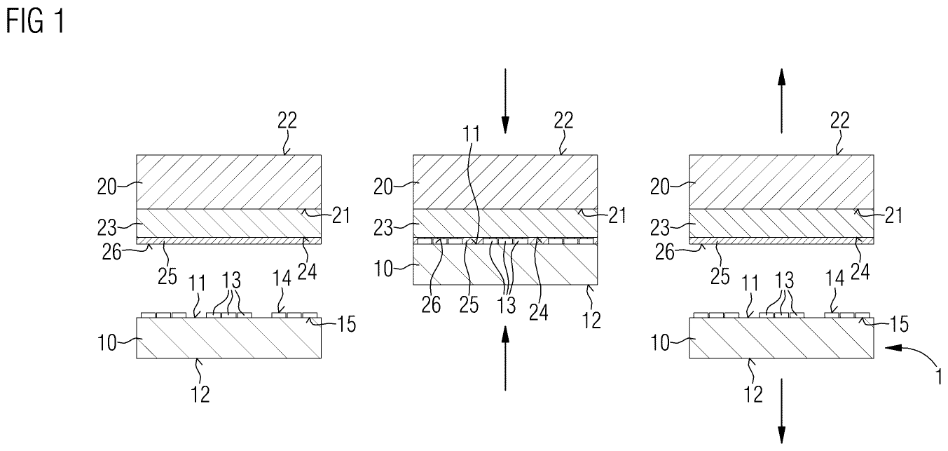

FIG. 1 schematically shows method steps of a method for producing an electronic component 1. The electronic component, its constituent parts, and elements used in the scope of the method, are each represented in a cross-sectional view.

The electronic component 1 is produced by connecting an electronic semiconductor chip 13 with a form fit to a carrier 10. The carrier 10 comprises by way of example silicon. The carrier 10 may for example be configured as a silicon wafer. The carrier 10 may however also comprise a different material, for example a different semiconductor, an oxide, a semiconductor oxide or a ceramic. The carrier 10 may also be configured as a circuit board or as a so-called flat no-leads substrate, for instance as a QFN substrate (quad-flat no-leads).

The carrier 10 has an upper side 11 and a lower side 12 opposite to the upper side 11. In the method, the carrier 10 is initially provided having at least one electronic semiconductor chip 13 arranged on the upper side 11 of the carrier 10. In the exemplary representation of FIG. 1, a total of nine electronic semiconductor chips 13 have been arranged on the upper side 11 of the carrier 10. The carrier 10 may, however, be provided having any desired number of electronic semiconductor chips 13 arranged on the carrier 10. The electronic semiconductor chips 13 each have upper sides 14 and lower sides 15. The electronic semiconductor chips 13 are arranged with their lower sides 15 on the upper side 11 of the carrier 10.

The electronic semiconductor chips 13 are configured by way of example as optoelectronic semiconductor chips 13. Further, in the exemplary embodiment, the optoelectronic semiconductor chips 13 are configured as light-emitting diodes (LEDs), in particular as micro-LEDs (μLEDs). The optoelectronic semiconductor chips 13 may, however, also be configured for example as laser diodes or as photodiodes. Depending on the intended use, for example, both LEDs and/or laser diodes and/or photodiodes may be used as optoelectronic semiconductor chips 13.

The electronic semiconductor chips 13 need not, however, necessarily be configured as optoelectronic semiconductor chips 13. The electronic semiconductor chips 13 may in principle comprise any desired application-specific electronic circuits, for example circuits having transistors and/or capacitors.

In the exemplary embodiment, the electronic component 1, which may be referred to as an optoelectronic component 1 since the electronic semiconductor chips 13 are configured by way of example as optoelectronic semiconductor chips 13, is a display device 1. The display device 1 comprises pixels, each of which is formed by way of example by three optoelectronic semiconductor chips 13 arranged directly next to one another. The optoelectronic semiconductor chips 13 are configured to emit electromagnetic radiation on their upper sides 14. The optoelectronic semiconductor chips 13 of each pixel of the display device 1 are configured by way of example as RGB LEDs. For each pixel, one LED configured to emit red light, one configured to emit green light and one configured to emit blue light are arranged on the carrier 10. Since the optoelectronic semiconductor chips 13 have upper sides 14 which are configured as radiation emission surfaces, the optoelectronic semiconductor chips 13 need to be connected particularly gently to the carrier 10 in order not to damage the optoelectronic semiconductor chips 13 and to ensure a good quality of display device 1.

A solder material (which is not shown in FIG. 1 for the sake of simplicity) may be arranged between the electronic semiconductor chips 13 and the carrier 10. The solder material is configured to establish a material bond between the electronic semiconductor chips 13 and the carrier 10. The solder material may comprise for example gold and indium, gold and tin or gold, indium and tin. The solder material may, however, also comprise other materials. Depending on the solder material used, the connecting between the electronic semiconductor chips 13 and the carrier 10 may take place for example at different temperatures. For example, adding tin to the solder material reduces the melting point of the solder material. The solder material may also be omitted. The connections between the electronic semiconductor chips 13 and the carrier 10 may, for example, also be generated by direct bonding.

In the method, a substrate 20 having a functional layer 23 arranged on the substrate 20 is further provided. The substrate 20 comprises by way of example silicon. The substrate 20 may, for example, be configured as a wafer. The substrate 20 may, however, also comprise a different material. The substrate 20 has an upper side 21 and a lower side 22 opposite to the upper side 21. The functional layer 23 is arranged on the upper side 21 of the substrate 20. The functional layer 23 has an upper side 24 facing away from the upper side 21 of the substrate 20. The providing of the substrate 20 may also comprise arranging the functional layer 23 on the substrate 20.

The functional layer 23 may for example comprise a polymer, an elastomer, a thermoplastic or an epoxy resin. By way of example, the functional layer 23 of FIG. 1 comprises a polymer based on benzocyclobutene (BCB). BCB may, for example, be arranged on the upper side 21 of the substrate 20 by spin coating.

In the exemplary embodiment of FIG. 1, a nonstick layer 25 is additionally arranged on the upper side 24 of the functional layer 23. The functional layer 23 is thus arranged between the substrate 20 and the nonstick layer 25. The nonstick layer 25 comprises by way of example a fluorinated material, which in the exemplary embodiment is perfluorodecyltrichlorosilane (FDTS). The nonstick layer may, however, also comprise a different material that reduces an adhesion to the electronic semiconductor chips 13.

The providing of the substrate 20 may also comprise arranging the nonstick layer 25 on the functional layer 23. The arranging of the nonstick layer 25 on the functional layer 23 may for example take place by vapor deposition, sputtering or spin coating. The arranging of the nonstick layer 25, or the nonstick layer 25 per se, may however also be omitted.

The substrate 20 is arranged over the carrier 10 in such a way that the upper side 24 of the functional layer 23 faces toward the upper sides 14 of the electronic semiconductor chips 13. If a nonstick layer 25 is provided, an upper side 26 of the nonstick layer 25 faces toward the upper sides 14 of the electronic semiconductor chips 13.

The substrate 20 is pressed onto the carrier 10. In this case, either the functional layer 23 is pressed with its upper side 24 onto the upper sides 14 of the electronic semiconductor chips 13 or, if the nonstick layer 25 is provided, the upper side 26 of the nonstick layer 25 is pressed onto the upper sides 14 of the electronic semiconductor chips 13. The electronic semiconductor chips 13 are therefore pressed onto the carrier 10 and connected to the carrier 10. During the pressing of the substrate 20 onto the carrier 10, the functional layer 23 deforms. In this way, a uniform application pressure is exerted on the electronic semiconductor chips 13. By the deformation of the functional layer 23, the electronic semiconductor chips 13 are protected against damage.

The method, and in particular the pressing of the substrate 20 onto the carrier 10, may for example take place in a so-called wafer bonder or a different bonding apparatus for substrates. For example, a surface pressure of from 2 bar to 9 bar may be used in order to press the substrate 20 onto the carrier 10. This value indication is merely exemplary. The pressure with which the substrate 20 is pressed onto the carrier 10 depends, for example, on a diameter of the substrate 20 and of the carrier 10 and on dimensions of the electronic semiconductor chips 13. Furthermore, the pressure with which the substrate 20 is pressed onto the carrier 10 is dependent on the material of the functional layer 23, or on its elasticity and its bulk modulus.

The functional layer 23 may optionally be heated during the pressing of the functional layer 23, or of the nonstick layer 25, onto the electronic semiconductor chips 13 in order to promote a deformation of the functional layer 23, or in order to increase the elasticity and reduce the bulk modulus. The functional layer 23 should be stable in terms of its chemical properties, for example up to a temperature of from 180° C. to 200° C., in order to enable reliable connecting of the electronic semiconductor chips 13 to the carrier 10 and, for example, not to be subjected to any modification and/or restructuring processes. The temperature values indicated are merely to be understood as exemplary value indications.

In addition, the carrier 10 may also be heated during the pressing of the functional layer 23, or of the nonstick layer 25, onto the electronic semiconductor chips 13 in order to generate a reliable connection between the electronic semiconductor chips 13 and the carrier 10. The temperature to be used also depends on the solder material optionally used, since it influences a viscosity of the solder material. The carrier 10 may, for example, be heated to a temperature of 170° C. The temperature indicated is, however, to be understood as not restrictive but merely as an exemplary indication. The temperature required also depends for example on the bonding technique used, on the materials used for the carrier 10 and optionally for the solder material, and dimensions of the carrier 10 and of the solder material. The solder material may for example have a thickness of from 100 nm to 600 nm, although this thickness is not restricted to the value range indicated. The position at which the temperature of the carrier 10 is measured is furthermore relevant. For example, temperature measurements on the upper side 11 of the carrier 10 may deliver significantly different temperature values than temperature measurements on the lower side 12 of the carrier 10.

The substrate 20 and the carrier 10 may be separated from one another again after the pressing. In this case, either the functional layer 23 or the nonstick layer 25 is detached from the electronic semiconductor chips 13. The nonstick layer 25 may bring about detaching that is more resistance-free. The nonstick layer 25 may furthermore have the effect that the electronic semiconductor chips 13 are not undercut by the material of the functional layer 23. Detaching of the electronic semiconductor chips 13 from the carrier 10 may therefore be avoided during the separation of the substrate 20 and the carrier 10. After the separation of the substrate 20 and the carrier 10, the production of the electronic component 1 is concluded. Where appropriate, curing of the solder material is also necessary.

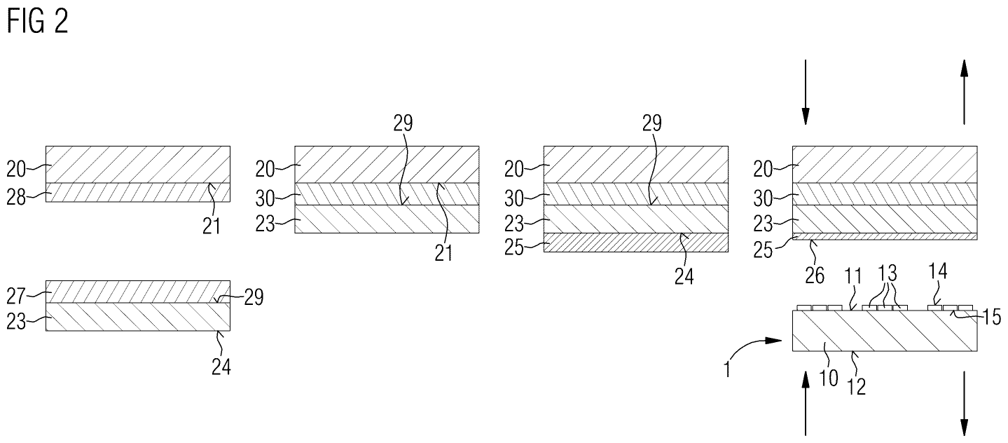

FIG. 2 schematically shows a variant of the method shown in FIG. 1. Again, the elements respectively represented are in each case represented in a cross-sectional view. The method variant of FIG. 2 has great similarities with the method of FIG. 1. In what follows, only the differences will be explained. Similar or identical elements are provided with the same reference signs in FIG. 2 as in FIG. 1.

In this variant, the functional layer 23 comprises graphite, or a graphite layer. The graphite layer may for example be arranged on the substrate 20 with the aid of a bonding method, as is shown in FIG. 2. The graphite layer may, however, also be arranged on the substrate 20 by vapor deposition or sputtering. In the bonding method, a graphite layer is used which may initially be cut and stamped into shape, and the graphite layer may for example be stamped with a diameter of the size of the substrate 20. The graphite layer may further have a thickness of 500 μm, for example, although the thickness is not restricted to this value indication.

A first adhesion promoter layer 27 is arranged on a lower side 29 of the graphite layer opposite to the upper side 24 of the graphite layer. The first adhesion promoter layer 27 comprises by way of example platinum, titanium and gold, which are arranged successively in layers above one another on the upper side 24 of the graphite layer. A platinum layer may, for example, have a thickness of 20 nm. A titanium layer may, for example, have a thickness of 200 nm. A gold layer may, for example, have a thickness of 2000 nm. The indicated thicknesses of the metal layers are merely exemplary indications. The first adhesion promoter layer 27 may, however, also comprise other materials or a material combination.

A second adhesion promoter layer 28 is arranged on the upper side 21 of the substrate 20. The second adhesion promoter layer 28 comprises by way of example titanium, tin, titanium and gold, which are arranged successively in layers above one another on the upper side 21 of the substrate 20. A first titanium layer may, for example, have a thickness of 200 nm. A tin layer may, for example, have a thickness of 650 nm. A second titanium layer may, for example, have a thickness of 5 nm. A gold layer may, for example, have a thickness of 150 nm. In this case as well, the indicated thicknesses of the metal layers are in each case merely exemplary indications. The second adhesion promoter layer 28 may also comprise other materials or a material combination.

The arranging of the graphite layer on the substrate 20 then takes place by bonding. In this case, the graphite layer is arranged over the substrate 20 in such a way that the first adhesion promoter layer 27, which is arranged on the lower side 29 of the graphite layer, faces toward the second adhesion promoter layer 28, which is arranged on the upper side 21 of the substrate 20. The adhesion promoter layers 27, 28 are then pressed onto one another. This may, for example, take place at a pressure of 8 bar and a temperature of 350° C. The bonding parameters for the connecting of the graphite layer to the substrate 20 may, however, also be selected differently. Because the adhesion promoter layers 27, 28 are pressed onto one another and at the same time heated, the adhesion promoter layers 27, 28 give rise to a bonding layer 30 which establishes a material bond between the graphite layer provided as a functional layer 23 and the substrate 20. Preferably, the graphite layer may be arranged in such a way that the atomic layers of strongly bound carbon of the graphite are arranged running substantially parallel to the upper side 21 of the substrate 20.

The optional nonstick layer 25 comprises a metallic material. In the present example, the nonstick layer 25 comprises titanium. The nonstick layer 25 may, however, also comprise for example gold. Graphite residues on the electronic component 1 are therefore avoided. The nonstick layer 25 comprising titanium may, for example, be arranged on the upper side 24 of the graphite layer by vapor deposition. The nonstick layer 25 may, however, also comprise for example a fluorinated material, for example FDTS. Conversely, in the case in which the functional layer 23 comprises a polymer, an elastomer, a thermoplastic, an epoxy resin or a different material, the nonstick layer 25 may also comprise a metallic material, for example titanium.

The substrate 20 faces with the graphite layer, or the optional nonstick layer 25, toward the electronic semiconductor chips 13, and is pressed onto the latter in order to connect it to the carrier 10 as has been described in connection with FIG. 1. The substrate 20 and the carrier 10 are subsequently separated from one another, the graphite layer or the optional nonstick layer 25 being detached from the electronic semiconductor chips 13.

The invention has been illustrated and described in detail with the help of the preferred exemplary embodiments. The invention is not, however, restricted to the examples disclosed. Rather, other variations may be derived therefrom by a person skilled in the art without departing from the protective scope of the invention.

1-17. (canceled)

18. A method for producing an electronic component, the method comprising:
providing a carrier having an electronic semiconductor chip arranged on the carrier;
providing a substrate having a functional layer arranged on the substrate;
arranging the substrate over the carrier such that the functional layer faces toward the electronic semiconductor chip; and
pressing the substrate onto the carrier,
wherein the functional layer is pressed onto the electronic semiconductor chip so that the electronic semiconductor chip is pressed onto the carrier and connected to the carrier, and
wherein the functional layer is deformed in response to pressing the electronic semiconductor chip.

19. The method according to claim 18, wherein the functional layer is elastically deformable.

20. The method according to claim 18, wherein the functional layer comprises a polymer, an elastomer, a thermoplastic or an epoxy resin.

21. The method according to claim 18, wherein the functional layer comprises benzocyclobutene.

22. The method according to claim 18, wherein the functional layer comprises graphite.

23. The method according to claim 18, wherein providing the substrate comprises arranging the functional layer on the substrate with aid of a bonding method, vapor deposition or sputtering.

24. The method according to claim 18, wherein the functional layer is heated when pressed onto the electronic semiconductor chip.

25. The method according to claim 18, further comprising:
arranging a nonstick layer on the functional layer,
wherein the functional layer is arranged between the substrate and the nonstick layer,
wherein the substrate is arranged over the carrier such that the nonstick layer faces toward the electronic semiconductor chip, and
wherein the nonstick layer is pressed onto the electronic semiconductor chip when the substrate is pressed onto the carrier.

26. The method according to claim 18,
wherein providing the substrate comprises arranging a nonstick layer on the functional layer by vapor deposition, sputtering or spin coating,
wherein the functional layer is arranged between the substrate and the nonstick layer, and
wherein the substrate is arranged over the carrier such that the nonstick layer faces toward the electronic semiconductor chip, the nonstick layer being pressed onto the electronic semiconductor chip while pressing the substrate onto the carrier.

27. The method according to claim 25, wherein the nonstick layer comprises a fluorinated material.

28. The method according to claim 27, wherein the nonstick layer comprises perfluorodecyltrichlorosilane.

29. The method according to claim 25, wherein the nonstick layer comprises a metallic material.

30. The method according to claim 29, wherein the metallic material is titanium or gold.

31. The method according to claim 25, further comprising:
separating the substrate and the carrier from one another after pressing,
wherein the nonstick layer or the functional layer is detached from the electronic semiconductor chip.

32. The method according to claim 18, wherein the electronic semiconductor chip is an optoelectronic semiconductor chip.

33. The method according to claim 18, further comprising arranging a solder material between the electronic semiconductor chip and the carrier.

34. The method according to claim 18, further comprising heating the carrier while pressing the functional layer onto the electronic semiconductor chip.

35. The method according to claim 18, wherein the carrier has a plurality of electronic semiconductor chips arranged on the carrier.
